(19) United States
(12) Patent Application Publication
(10) Pub. No.: US 2026/0035801 A1
(43) Pub. Date: Feb. 5, 2026

(54) COMPOSITION, METHOD OF TREATING METAL-CONTAINING LAYER BY USING THE SAME, AND METHOD OF MANUFACTURING SEMICONDUCTOR DEVICE BY USING THE SAME

(71) Applicant: Samsung Electronics Co., Ltd., Suwon-si (KR)

(72) Inventors: Insun PARK, Suwon-si (KR); Byungjoon KANG, Suwon-si (KR); Sungmin KIM, Suwon-si (KR); Jungah KIM, Suwon-si (KR); Juhee MOON, Suwon-si (KR); Minjae SUNG, Suwon-si (KR); Sabyuk YANG, Suwon-si (KR); Kum Hee LEE, Suwon-si (KR); Kyuyoung HWANG, Suwon-si (KR)

(73) Assignee: Samsung Electronics Co., Ltd., Suwon-si (KR)

(21) Appl. No.: 19/273,781

(22) Filed: Jul. 18, 2025

(30) Foreign Application Priority Data
Aug. 2, 2024 (KR) 10-2024-0103269

(51) Int. Cl. C23F 1/26; H01L 21/3213

(52) U.S. Cl. CPC C23F 1/26; H01L 21/32134

(57) ABSTRACT

Provided are a composition, a method of treating a metal-containing layer by using the same, and/or a method of manufacturing a semiconductor device by using the same. The composition may include an oxidizing agent, an acid, and an etching controller, wherein the etching controller may include at least one compound represented by Formula 1:

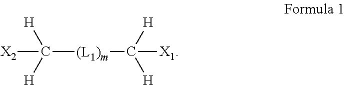

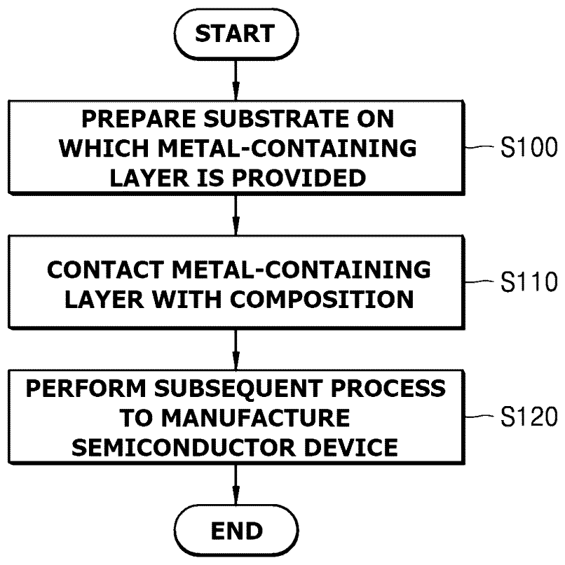

A description of Formula 1 is provided in the specification of the present application.

### CROSS-REFERENCE TO RELATED APPLICATION

This application is based on and claims priority under 35 USC § 119 to Korean Patent Application No. 10-2024-0103269, filed on Aug. 2, 2024, in the Korean Intellectual Property Office, the disclosure of which is incorporated by reference herein in its entirety.

### BACKGROUND

### 1. Field

The disclosure relates to a composition, a method of treating a metal-containing layer by using the same, and/or a method of manufacturing a semiconductor device by using the same.

### 2. Description of the Related Art

To meet consumer demands for excellent performance and affordable prices, an increase in semiconductor device integration and an improvement in reliability may be required. As the integration of semiconductor devices increases, damage to the components of semiconductor devices during the manufacturing process thereof may have a greater impact on the reliability and/or electrical characteristics of semiconductor memory devices. In particular, during the semiconductor device manufacturing process, various treatment processes such as etching, cleaning, and polishing may be performed on certain layers (for example, metal-containing layers). To more effectively perform metal-containing layer treatment processes, compositions with appropriate etching rates and/or other properties may be needed.

### SUMMARY

Provided are a composition capable of more effectively controlling the etching rate of various metal-containing layers, for example, a metal-containing layer including molybdenum, a method of treating a metal-containing layer by using the same, and/or a method of manufacturing a semiconductor device by using the same.

Additional aspects will be set forth in part in the description which follows and, in part, will be apparent from the description, or may be learned by practice of the presented embodiments of the disclosure.

According to an example embodiment, a composition may include an oxidizing agent, an acid, and an etching controller, wherein the etching controller may include at least one compound represented by Formula 1:

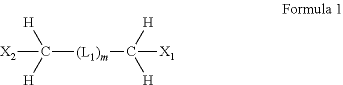

wherein in Formula 1,
X₁ may be *—OH or *—SH,
X₂ may be hydrogen, *—OH, or *—SH,
each L₁ independently may be *—C(R₁)(R₂)—*′, *—O—*′ or *—S—*′, provided that a number of *—O—*′ or *—S—*′ in (L₁)ₘ may be 0 or 1,
m may be an integer from 1 to 30,
when m is an integer from 2 to 30, each L₁ in (L₁)ₘ may be identical to different from another L₁ in (L₁)ₘ,
R₁ and R₂ may each independently be hydrogen or a C₁-C₁₀ alkyl group, and * and *′ each indicate a bonding site to a neighboring atom.

According to an example embodiment of the disclosure, a method of treating a metal-containing layer may include
preparing a substrate including a metal-containing layer thereon, and
contacting the metal-containing layer with the composition.

According to an example embodiment of the disclosure, a method of manufacturing a semiconductor device may include:
preparing a substrate including a metal-containing layer thereon,
contacting the metal-containing layer with the composition, and
performing one or more subsequent manufacturing processes.

### BRIEF DESCRIPTION OF THE DRAWING

The above and other aspects, features, and advantages of certain embodiments of the disclosure will be more apparent from the following description taken in conjunction with FIGURE which is a process flow diagram of an embodiment of a method of manufacturing a semiconductor device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the singular forms “a,” “an” and “the” are intended to include the plural forms as well, unless the context clearly indicates otherwise. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

### Metal-Containing Layer

A metal included in the metal-containing layer may be an alkali metal (for example, sodium (Na), potassium (K), rubidium (Rb), cesium (Cs), etc.), an alkaline earth metal (for example, beryllium (Be), magnesium (Mg), calcium (Ca), strontium (Sr), barium (Ba), etc.), a lanthanide metal (for example, lanthanum (La), europium (Eu), terbium (Tb), ytterbium (Yb), etc.), a transition metal (for example, scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), etc.), a post-transition metal (for example aluminum (Al), gallium (Ga), indium (In), thallium (Tl), tin (Sn), bismuth (Bi), etc.), or any combination thereof.

According to an embodiment, a metal included in the metal-containing layer may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), or any combination thereof.

For example, the metal-containing layer may include titanium, aluminum, lanthanum, tungsten, molybdenum, or any combination thereof.

The metal-containing layer may include a metal, a metal nitride, a metal oxide, a metal oxynitride, or any combination thereof.

According to an embodiment, the metal-containing layer may include a metal, a metal nitride, a metal oxide, a metal oxynitride, or any combination thereof. The metal contained in each of metal, metal nitride, metal oxide and metal oxynitride may include titanium (Ti), indium (In), aluminum (AI), cobalt (Co), lanthanum (La), scandium (Sc), gallium (Ga), tungsten (W), molybdenum (Mo), ruthenium (Ru), zinc (Zn), hafnium (Hf), copper (Cu), or any combination thereof.

In some embodiments, the metal-containing layer may include a metal as described above.

In some embodiments, the metal-containing layer may include a metal nitride. The metal included in the metal nitride may include indium, titanium, aluminum, lanthanum, scandium, gallium, zinc, hafnium, or any combination thereof.

For example, the metal-containing layer may include titanium nitride. The titanium nitride may further include indium, aluminum, lanthanum, scandium, gallium, hafnium, zinc, tungsten, silicon, or any combination thereof. In some embodiments, the metal-containing layer may include titanium nitride (TiN), titanium nitride further including aluminum (for example, titanium/aluminum nitride or TiAlN), titanium nitride further including lanthanum, titanium nitride further including silicon (TiSiN), and the like.

In some embodiments, the metal-containing layer may include a metal oxide. The metal included in the metal oxide may include titanium, aluminum, lanthanum, scandium, gallium, hafnium, or any combination thereof. For example, the metal-containing layer may include aluminum oxide (for example, Al₂O₃), indium gallium zinc oxide (IGZO), etc.

In some embodiments, the metal-containing layer may further include, in addition to the metal, a metalloid (for example, boron (B), silicon (Si), germanium (Ge), arsenic (As), antimony (Sb), tellurium (Te), etc.), a non-metal (for example, nitrogen (N), phosphorus (P), oxygen (O), sulfur (S), selenium (Se), etc.), or any combination thereof. For example, the metal-containing layer may further include silicon oxide.

In some embodiments, the metal-containing layer may include the metal and the metal nitride.

According to an embodiment, the metal-containing layer may include molybdenum. In some embodiments, the metal-containing layer may further include, in addition to molybdenum, i) titanium nitride or ii) titanium nitride further including indium, aluminum, lanthanum, scandium, gallium, hafnium, zinc, tungsten, silicon, or any combination thereof.

The metal-containing layer may have a single-layer structure including one or more types of materials, or a multi-layer structure or three-dimensional pattern structure including different materials. For example, the metal-containing layer may have i) a double-layer structure or a three-dimensional pattern structure including a region including (or consisting of) titanium nitride and a region including (or consisting of) molybdenum, ii) a double-layer structure or a three-dimensional pattern structure including a region including (or consisting of) titanium nitride further including silicon and a region including (or consisting of) molybdenum, etc.

### Composition

The composition may include an oxidizing agent, an acid, and an etching controller.

The composition may be used in various treatment processes for the metal-containing layer described herein, for example, an etching process, a cleaning process, a polishing process, etc.

The composition may further include water.

According to an embodiment, the composition may consist of (or include) an oxidizing agent, an acid, an etching controller, and water.

### Oxidizing Agent

The oxidizing agent may etch at least a portion of the metal-containing layer and may include, for example, at least one of hydrogen peroxide, nitric acid, and ammonium sulfate.

According to an embodiment, the oxidizing agent may include at least one of hydrogen peroxide and nitric acid.

In some embodiments, the oxidizing agent may include nitric acid.

In some embodiments, the oxidizing agent may include hydrogen peroxide.

The amount (weight) of the oxidizing agent may be, for example, based on 100 wt % of the composition, about 0.001 wt % to about 50 wt %, about 0.001 wt % to about 40 wt %, about 0.001 wt % to about 30 wt %, about 0.001 wt % to about 20 wt %, about 0.001 wt % to about 10 wt %, about 0.001 wt % to about 5 wt %, about 0.001 wt % to about 4.8 wt %, about 0.01 wt % to about 50 wt %, about 0.01 wt % to about 40 wt %, about 0.01 wt % to about 30 wt %, about 0.01 wt % to about 20 wt %, about 0.01 wt % to about 10 wt %, about 0.01 wt % to about 5 wt %, about 0.01 wt % to about 4.8 wt %, about 0.1 wt % to about 50 wt %, about 0.1 wt % to about 40 wt %, about 0.1 wt % to about 30 wt %, about 0.1 wt % to about 20 wt %, about 0.1 wt % to about 10 wt %, about 0.1 wt % to about 5 wt %, about 0.1 wt % to about 4.8 wt %, about 0.5 wt % to about 50 wt %, about 0.5 wt % to about 40 wt %, about 0.5 wt % to about 30 wt %, about 0.5 wt % to about 20 wt %, about 0.5 wt % to about 10 wt %, about 0.5 wt % to about 5 wt %, or about 0.5 wt % to about 4.8 wt %.

### Acid

The acid, together with the oxidizing agent, may etch at least a portion of the metal-containing layer.

The acid may include an inorganic acid, an organic acid, or any combination thereof.

In an embodiment, the acid may be an inorganic acid.

In some embodiments, the acid may include at least one of phosphoric acid, sulfuric acid, and hydrofluoric acid.

In some embodiments, the acid may include phosphoric acid.

The amount (weight) of the acid may be, for example, based on 100 wt % of the composition, about 0.01 wt % to about 90 wt %, about 0.1 wt % to about 90 wt %, about 1 wt % to about 90 wt %, about 10 wt % to about 90 wt %, about 20 wt % to about 90 wt %, about 30 wt % to about 90 wt %, about 0.01 wt % to about 80 wt %, about 0.1 wt % to about 80 wt %, about 1 wt % to about 80 wt %, about 10 wt % to about 80 wt %, about 20 wt % to about 80 wt %, about 30 wt % to about 80 wt %, about 0.01 wt % to about 70 wt %, about 0.1 wt % to about 70 wt %, about 1 wt % to about 70 wt %, about 10 wt % to about 70 wt %, about 20 wt % to about 70 wt %, about 30 wt % to about 70 wt %, about 0.01 wt % to about 60 wt %, about 0.1 wt % to about 60 wt %, about 1 wt % to about 60 wt %, about 10 wt % to about 60 wt %, about 20 wt % to about 60 wt %, or about 30 wt % to about 60 wt %.

Etching controller

The etching controller may interact with various metal atoms in the metal-containing layer, which is the target layer, to control the etching rate, etc.

The etching controller may include at least one compound represented by Formula 1:

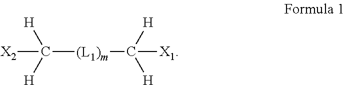

In Formula 1,
X₁ may be *—OH or *—SH,
X₂ may be hydrogen, *—OH, or *—SH,
each L₁ independently may be *—C(R₁)(R₂)—*′, *—O—*′ or *—S—*′, provided that a number of *—O—*′ or *—S—*′ in (L₁)ₘ may be 0 or 1,
m may be an integer from 1 to 30,
when m is an integer from 2 to 30, each L₁ in (L₁)ₘ may be identical to or different from another L₁ in (L₁)ₘ,
R₁ and R₂ may each independently be hydrogen or a C₁-C₁₀ alkyl group, and
* and *′ each indicate a bonding site to a neighboring atom.

According to an embodiment, in Formula 1, X₁ may be *—OH, X₂ may be hydrogen or *—OH, and each L₁ in (L₁)ₘ may be *—C(R₁)(R₂)—*′ or *—O—*′.

In some embodiments, in Formula 1, each L₁ may not be *—S—*′.

In some embodiments, X₂ in Formula 1 may be *—OH or *—SH.

In some embodiments, X₂ in Formula 1 may be hydrogen.

In some embodiments, m in Formula 1 may be an integer from 1 to 20, an integer from 1 to 15, an integer from 1 to 10, an integer from 1 to 8, or an integer from 1 to 6.

In some embodiments, L₁ in Formula 1 may be *—C(R₁)(R₂)—*′.

In some embodiments, one of L₁ in the number of m of Formula 1 may be *—O—*′ or *—S—*′.

In some embodiments, R₁ and R₂ of Formula 1 may each independently be hydrogen, a methyl group, an ethyl group, or a propyl group.

In some embodiments, each of R₁ and R₂ of Formula 1 may be hydrogen.

In some embodiments, the etching controller may include at least one of compounds represented by Formula 1(1), at least one of compounds represented by Formula 1(2), or any combination thereof:

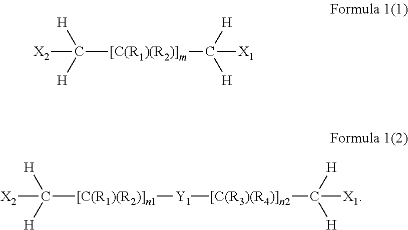

In Formulae 1(1) and 1(2),
each of X₁, X₂, m, R₁ and R₂ is as described in this specification,
Y₁ may be O or S,
n1 and n2 may each independently be an integer from 0 to 29,
the sum of n1 and n2 may be an integer from 0 to 29,
each of R₃ and R₄ is as described in connection with R₁ in this specification, and
* is a bonding site with a neighboring atom.

For example, in Formulae 1(1) and 1(2),
X₁ may be *—OH or *—SH,
X₂ may be hydrogen, *—OH, or *—SH,
Y₁ may be O or S,
m may be an integer from 1 to 30,
n1 and n2 may each independently be an integer from 0 to 29,
the sum of n1 and n2 may be an integer from 0 to 29,
R₁ to R₄ may each independently be hydrogen or a C₁-C₁₀ alkyl group, and
* is a bonding site with a neighboring atom.

According to an embodiment, m in Formula 1(1) may be an integer from 1 to 20, an integer from 1 to 15, an integer from 1 to 10, an integer from 1 to 8, or an integer from 1 to 6.

In some embodiments, n1 and n2 in Formula 1(2) may each independently be an integer from 0 to 19, and the sum of n1 and n2 may be an integer from 0 to 19.

In some embodiments, n1 and n2 in Formula 1(2) may each independently be an integer from 0 to 14, and the sum of n1 and n2 may be an integer from 0 to 14.

In some embodiments, n1 and n2 in Formula 1(2) may each independently be an integer from 0 to 9, and the sum of n1 and n2 may be an integer from 0 to 9.

In some embodiments, n1 and n2 in Formula 1(2) may each independently be an integer from 0 to 7, and the sum of n1 and n2 may be an integer from 0 to 7.

In some embodiments, n1 and n2 in Formula 1(2) may each independently be an integer from 0 to 5, and the sum of n1 and n2 may be an integer from 0 to 5. In some embodiments, n1 and n2 in Formula 1(2) may each independently be an integer from 0 to 4, 0 to 3, 0 to 2, or 1, and the sum of n1 and n2 may be an integer from 0 to 4, 0 to 3, or 0 to 2.

In some embodiments, the etching controller may include at least one of compounds represented by Formulae 2(1) to 2(8), at least one of compounds represented by Formulae 3(1) to 3(13), or any combination thereof:

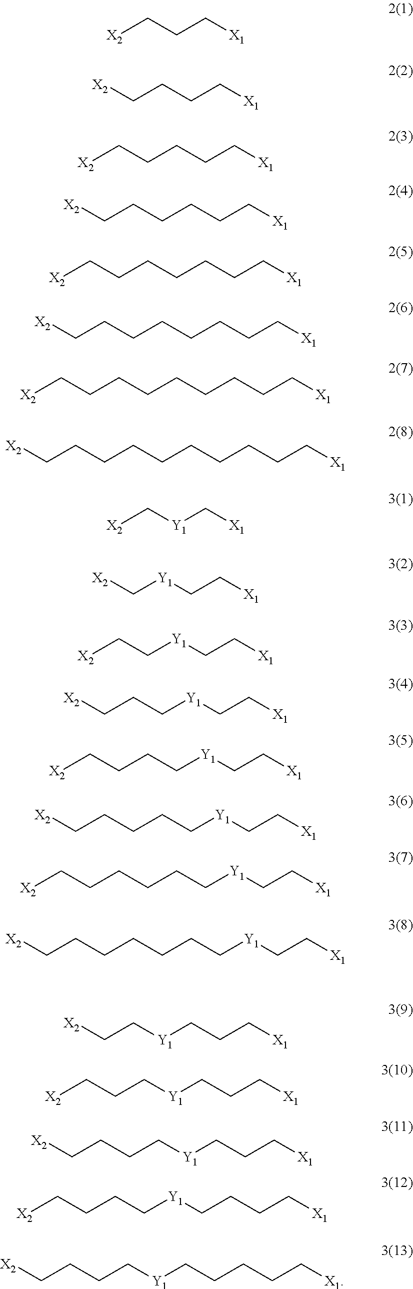

In Formulae 2(1) to 2(8) and 3(1) to 3(13),

X₁ may be *—OH or *—SH,

X₂ may be hydrogen, *—OH, or *—SH, and

Y₁ may be O or S.

In some embodiments, the etching controller may include at least one of Compounds E1 to E11:

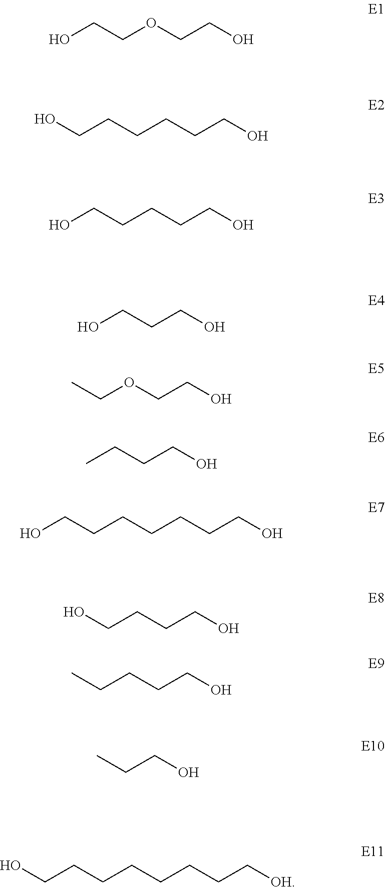

Although not intended to be limited to a particular theory, a compound represented by Formula 1 where m is 0 or R₁ is a hydroxyl group (for example, Compounds A5, A3, etc. below) may be bonded to a metal, for example, molybdenum, to form a water-soluble complex having a stable 5-membered cyclometallated ring, and thus, may promote the etching of a metal-containing layer (see Comparative Example C4 in Table 2, Comparative Example C5 in Table 3, etc.).

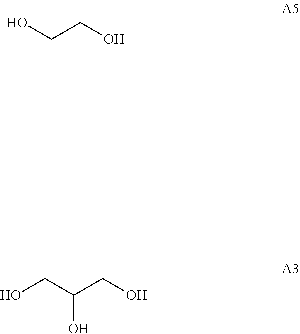

In addition, although not intended to be limited to a particular theory, a compound represented by Formula 1 where the number of *—O—*′ or *—S—*′ in L₁ in the number of m is 2 or more (for example, compounds A8, A4, etc.), have substantially little interaction with a metal, such as molybdenum, and thus may not protect a metal such as molybdenum, and thus may not limit and/or suppress etching of a metal-containing layer (see Comparative Example C6 in Table 4, Comparative Example C7 in Table 4, etc.).

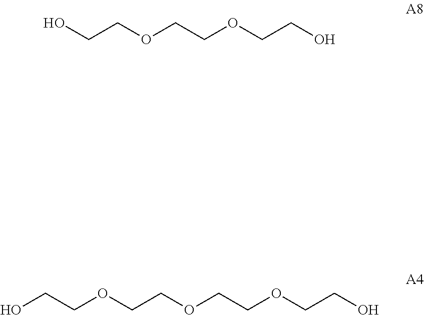 [SMILES: OCCOCCOCCO ; OCCOCCOCCOCCO]

However, a compound represented by Formula 1 where the number of *—O—*′ or *—S—*′ in L₁ in the number of m is 0 or 1 and each of R₁ and R₂ is hydrogen or a C1-C10 alkyl group, i) does not form a water-soluble complex having a 5-membered cyclometallated ring by bonding to a metal, for example, molybdenum, and ii) may have a molecular size and/or molecular structure capable of forming a relatively weak chemical bond with a metal, for example, molybdenum, and may maintain improved and/or excellent stability even when mixed with an acid. Accordingly, the compound may be located around a metal, such as molybdenum and may substantially limit and/or prevent the metal, such as molybdenum, from being etched.

Therefore, when the composition including the compound represented by Formula 1 comes into contact with various metal-containing layers, for example, a metal-containing layer including molybdenum, the compound represented by Formula 1 may limit and/or suppress the etching of molybdenum, thereby controlling the etching rate of molybdenum.

The amount (weight) of the etching controller may be, for example, based on 100 wt % of the composition, about 0.01 wt % to about 20 wt %, about 0.01 wt % to about 15 wt %, about 0.01 wt % to about 10 wt %, about 0.1 wt % to about 20 wt %, about 0.1 wt % to about 15 wt %, about 0.1 wt % to about 10 wt %, about 1 wt % to about 20 wt %, about 1 wt % to about 15 wt %, about 1 wt % to about 10 wt %, about 3 wt % to about 20 wt %, about 3 wt % to about 15 wt %, about 3 wt % to about 10 wt %, about 5 wt % to about 20 wt %, about 5 wt % to about 15 wt %, or about 5 wt % to about 10 wt %.

The composition as described above may have a pH of 5.0 or less, 4.0 or less, 3.0 or less, 2.0 or less, 1.0 or less, −2.0 to 5.0, −2.0 to 4.0, −2.0 to 3.0, −2.0 to 2.0, −2.0 to 1.0, 0.01 to 5.0, 0.01 to 4.0, 0.01 to 3.0, 0.01 to 2.0, 0.01 to 1.0, 0.1 to 5.0, 0.1 to 4.0, 0.1 to 3.0, 0.1 to 2.0, 0.1 to 1.0, 0.5 to 5.0, 0.5 to 4.0, 0.5 to 3.0, 0.5 to 2.0, or 0.5 to 1.0. Since the composition has such ranges of pH, the interaction between the etching controller and the metal atoms in the metal-containing layer may occur more smoothly.

According to an embodiment, the composition may be used in a treatment process for a metal-containing layer, for example, an etching process, a cleaning process, a polishing process, etc. for a metal-containing layer. The metal-containing layer is as described herein.

Alternatively, the composition may also be used as an etching byproduct remover, a post-etch process byproduct remover, an ashing process byproduct remover, a cleaning composition, a photoresist (PR) remover, an etching composition for packaging process, a cleaner for packaging process, a wafer adhesive material remover, an etchant, a post-etch residue stripper, an ash residue cleaner, a photoresist residue stripper, a chemical mechanical polishing (CMP) cleaner, or a post-CMP cleaner.

### Metal-Containing Layer Treatment Method and Semiconductor Device Manufacturing Method

A metal-containing layer may be effectively treated by using the composition described above.

Referring to FIGURE, an example of the method of treating a metal-containing layer may include: preparing a substrate on which a metal-containing layer is provided (S100); and contacting the metal-containing layer with a composition as described herein (S110).

The metal-containing layer is as described herein.

For example, metal included in the metal-containing layer may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), or any combination thereof.

In some embodiments, the metal-containing layer may include a metal, a metal nitride, a metal oxide, a metal oxynitride, or any combination thereof.

According to an embodiment, the metal-containing layer may include a metal as described above.

In some embodiments, the metal-containing layer may include a metal nitride. The metal included in the metal nitride may include indium, titanium, aluminum, lanthanum, scandium, gallium, zinc, hafnium, or any combination thereof.

In some embodiments, the metal-containing layer may include titanium nitride. The titanium nitride may further include indium, aluminum, lanthanum, scandium, gallium, hafnium, zinc, tungsten, silicon, or any combination thereof. In some embodiments, the metal-containing layer may include titanium nitride (TiN), titanium nitride further including aluminum (for example, titanium/aluminum nitride or TiAlN), titanium nitride further including lanthanum, titanium nitride further including silicon (TiSiN), and the like.

According to an embodiment, due to the contacting of the metal-containing layer with the composition, at least a portion of the metal-containing layer may be etched, cleaned, or polished.

In some embodiments, the metal-containing layer may include molybdenum. In some embodiments, the metal-containing layer may further include, in addition to molybdenum, i) titanium nitride or ii) titanium nitride further including indium, aluminum, lanthanum, scandium, gallium, hafnium, zinc, tungsten, silicon or any combination thereof.

In some embodiments, the metal-containing layer includes a first region and a second region, and a value (ER2/ER1) obtained by dividing a second etching rate at which the composition etches the second region by a first etching rate at which the composition etches the first region may be about 0.5 to about 2.

For example, the second region may include molybdenum, and the first region may include i) a metal nitride or ii) a metal nitride further including indium, aluminum, lanthanum, scandium, gallium, hafnium, zinc, tungsten, silicon, or any combination thereof. In some embodiments, the second region may include molybdenum, and the first region may include i) a titanium nitride or ii) a titanium nitride further including indium, aluminum, lanthanum, scandium, gallium, hafnium, zinc, tungsten, silicon, or any combination thereof.

Since the composition includes an etching controller including a compound represented by Formula 1 as described above, etching rates for various metal-containing layers may be easily controlled.

Referring to FIGURE, a method of manufacturing a semiconductor device according to an embodiment may include: preparing a substrate on which a metal-containing layer is provided (S100); contacting the metal-containing layer with the composition (S110); and performing a subsequent process (e.g., deposition process, etching process, photolithography process) on the substrate to manufacture a semiconductor device (S120) after the contacting the metal-containing layer with the composition (S110).

### Examples 1 to 3 and Comparative Examples C1 to C3

The compositions of Examples 1 to 3 and Comparative Examples C1 to C3 were prepared by mixing materials weighed according such amounts shown in Table 1 and presented as an oxidizing agent, an acid, and an etching controller. The remainder of each composition corresponds to water (deionized water).

### Evaluation Example 1

The composition of Example 1 was placed in a beaker and heated to 60° C. Then, a molybdenum layer (Mo layer) specimen having the size of 1 cm×1 cm was immersed in the beaker for 0.5 minutes, and then, the thickness of the molybdenum layer was measured by using an ellipsometer (M-2000, JAWoolam), a four-point resistance meter, and XRF (X-ray fluorescence), and the etching rate (Å/min) of the molybdenum layer of the composition of Example 1 was evaluated. Results thereof are summarized in Table 1.

This test was repeated using each of the compositions of Examples 2 to 3 and Comparative Examples C1 to C3. Results are summarized in Table 1.

TABLE 1

| | |
|---|---|
| Oxidizing | Molybdenum layer |

| | | | |
|---|---|---|---|
| agent | Acid | Etching controller | (Å/min) |

| | Materi- | Amount | Materi- | Amount | | Amount | Immersion time |
|---|---|---|---|---|---|---|---|
| | al | (wt %) | al | (wt %) | Material | (wt %) | (0.5 minutes) |
| Example | Nitric | 4.8 | Phos- | 30 | E1 | 5 | 58.1 |
| 1 | acid | | phoric | | | | |
| | | | acid | | | | |
| Example | Nitric | 4.8 | Phos- | 30 | E1 | 7 | 42.2 |
| 2 | acid | | phoric | | | | |
| | | | acid | | | | |
| Example | Nitric | 4.8 | Phos- | 30 | E1 | 10 | 16.3 |
| 3 | acid | | phoric | | | | |
| | | | acid | | | | |
| Compa- | Nitric | 4.8 | Phos- | 30 | — | — | 388.3 |
| rative | acid | | phoric | | | | |
| Example | | | acid | | | | |
| C1 | | | | | | | |
| Compa- | Nitric | 4.8 | Phos- | 30 | A1 | 7 | 379.5 |
| rative | acid | | phoric | | | | |
| Example | | | acid | | | | |
| C2 | | | | | | | |
| Compa- | Nitric | 4.8 | Phos- | 30 | A2 | 7 | 381.9 |
| rative | acid | | phoric | | | | |
| Example | | | acid | | | | |
| C3 | | | | | | | |

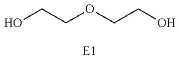

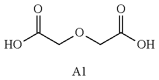

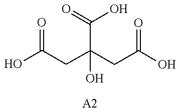

From Table 1, it can be confirmed that the compositions of Examples 1 to 3 have superior etching inhibition performance for a molybdenum layer compared to the compositions of Comparative Examples C1 to C3.

### Comparative Example C4 and Examples 4 to 9

The compositions of Comparative Example C4 and Examples 4 to 9 were prepared by mixing materials weighed according such amounts shown in Table 2 and presented as an oxidizing agent, an acid, and an etching controller. The remainder of each composition corresponds to water (deionized water).

### Evaluation Example 2

The etching rates (Å/min) for the molybdenum layer of each of the compositions of Comparative Example C4 and Examples 4 to 9 were evaluated in the same manner as Evaluation Example 1, except that the immersion time was changed to 1 minute. Results thereof are summarized in Table 2.

TABLE 2

Molybdenum
layer

| | |
|---|---|
| Oxidizing | etching rate |

| | | | |
|---|---|---|---|
| agent | Acid | Etching controller | (Å/min) |

| | Materi- | Amount | Materi- | Amount | | Amount | Immersion time |
|---|---|---|---|---|---|---|---|
| | al | (wt %) | al | (wt %) | Material | (wt %) | (1 minute) |
| Compara- | Nitric | 4.8 | Phos- | 30 | A5 | 7 | 200 or more |
| tive | acid | | phoric | | | | |
| Example | | | acid | | | | |
| C4 | | | | | | | |
| Example | Nitric | 4.8 | Phos- | 30 | E4 | 7 | 12.1 |
| 4 | acid | | phoric | | | | |
| | | | acid | | | | |
| Example | Nitric | 4.8 | Phos- | 30 | E3 | 7 | 24.8 |
| 5 | acid | | phoric | | | | |
| | | | acid | | | | |
| Example | Nitric | 4.8 | Phos- | 30 | E2 | 7 | 70 |
| 6 | acid | | phoric | | | | |
| | | | acid | | | | |
| Example | Nitric | 4.8 | Phos- | 30 | E7 | 7 | 16.6 |
| 7 | acid | | phoric | | | | |
| | | | acid | | | | |
| Example | Nitric | 4.8 | Phos- | 30 | E6 | 7 | 1.9 |
| 8 | acid | | phoric | | | | |
| | | | acid | | | | |
| Example | Nitric | 4.8 | Phos- | 30 | E11 | 7 | 4.7 |
| 9 | acid | | phoric | | | | |
| | | | acid | | | | |

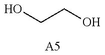

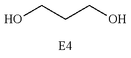

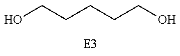

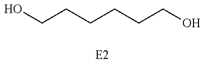

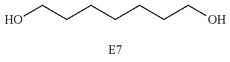

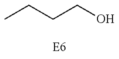

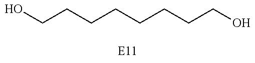

From Table 2, it can be confirmed that the compositions of Examples 4 to 9 have superior etching inhibition performance for a molybdenum layer compared to the composition of Comparative Example C4.

### Comparative Example C5

A composition of Comparative Example C5 was prepared by mixing materials weighed according such amounts shown in Table 3 and presented as an oxidizing agent, an acid, and an etching controller. The remainder of each composition corresponds to water (deionized water).

### Evaluation Example 3

The etching rate (Å/min) of the composition of Comparative Example C5 for a molybdenum layer was evaluated in the same manner as Evaluation Example 1, except that the immersion time was changed to 1 minute, and a result thereof is summarized in Table 3 together with the etching rate of the composition of Example 4 for a molybdenum layer.

TABLE 3

| | | | | | | | Molybdenum layer |
|---|---|---|---|---|---|---|---|
| | Oxidizing | | | | | | etching rate |
| | agent | | Acid | | Etching controller | | (Å/min) |
| | Materi- | Amount | Materi- | Amount | | Amount | Immersion time |
| | al | (wt %) | al | (wt %) | Material | (wt %) | (1 minute) |
| Example | Nitric | 4.8 | Phos- | 30 | E4 | 7 | 12.1 |
| 4 | acid | | phoric | | | | |
| | | | acid | | | | |
| Compara- | Nitric | 4.8 | Phos- | 30 | A3 | 7 | 200 or more |
| tive | acid | | phoric | | | | |
| Example | | | acid | | | | |
| C5 | | | | | | | |

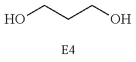

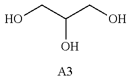

From Table 3, it can be confirmed that the composition of Example 4 has improved etching inhibition performance for a molybdenum layer compared to the composition of Comparative Example C5.

### Example 10 and Comparative Examples C6 and C7

The compositions of Example 10 and Comparative Examples C6 and C7 were respectively prepared by mixing materials weighed according such amounts shown in Table 4 and presented as an oxidizing agent, an acid, and an etching controller. The remainder of each composition corresponds to water (deionized water).

### Evaluation Example 4

In the same method as Evaluation Example 1, the etching rate (Å/min) of each of the compositions of Example 10 and Comparative Examples C6 and C7 with respect to the molybdenum layer was evaluated, and results thereof are summarized in Table 4 together with the etching rate of the composition of Example 2 with respect to the molybdenum layer.

TABLE 4

Molybdenum layer

| | |
|---|---|
| Oxidizing | etching rate |

| | | | |
|---|---|---|---|
| agent | Acid | Etching controller | (Å/min) |

| | Materi- | Amount | Materi- | Amount | | Amount | Immersion time |
|---|---|---|---|---|---|---|---|
| | al | (wt %) | al | (wt %) | Material | (wt %) | (0.5 minutes) |
| Example | Nitric | 4.8 | Phos- | 30 | E1 | 7 | 42.2 |
| 2 | acid | | phoric | | | | |
| | | | acid | | | | |
| Example | Nitric | 4.8 | Phos- | 30 | E5 | 7 | 11.5 |
| 10 | acid | | phoric | | | | |
| | | | acid | | | | |
| Compara- | Nitric | 4.8 | Phos- | 30 | A8 | 7 | 200 or more |
| tive | acid | | phoric | | | | |
| Example | | | acid | | | | |
| C6 | | | | | | | |
| Compara- | Nitric | 4.8 | Phos- | 30 | A4 | 7 | 200 or more |
| ative | acid | | phoric | | | | |
| Example | | | acid | | | | |
| C7 | | | | | | | |

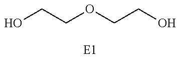

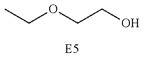

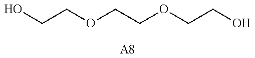

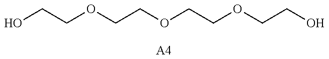

From Table 4, it can be confirmed that the compositions of Examples 2 and 10 have superior etching inhibition performance for molybdenum layers compared to the compositions of Comparative Examples C6 and C7.

### Example 11 and Comparative Example C8

The compositions of Example 11 and Comparative Example C8 were respectively prepared by mixing materials weighed according such amounts shown in Table 5 and presented as an oxidizing agent, an acid, and an etching controller. The remainder of each composition corresponds to water (deionized water).

### Evaluation Example 5

The etching rate (Å/min) of the molybdenum layer of each of the compositions of Example 11 and Comparative Example C8 was evaluated in the same method as Evaluation Example 1, and results thereof are summarized in Table 5.

TABLE 5

| | | | | | | | Molybdenum layer |
|---|---|---|---|---|---|---|---|
| | | | | | Etching | | etching rate |
| | Oxidizing agent | | Acid | | controller | | (Å/min) |
| | | Amount | Materi- | Amount | Ma- | Amount | Immersion time |
| | Material | (wt %) | al | (wt %) | terial | (wt %) | (0.5 minutes) |
| Example 11 | Hydrogen | 0.5 | Phos- | 30 | E4 | 7 | 250 |
| | peroxide | | phoric | | | | |
| | | | acid | | | | |
| Comparative | Hydrogen | 0.5 | Phos- | 30 | — | — | 324.6 |
| Example | peroxide | | phoric | | | | |
| C8 | | | acid | | | | |

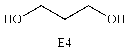

From Table 5, it can be confirmed that the composition of Example 11 has improved etching inhibition performance for a molybdenum layer compared to the composition of Comparative Example C8.

The composition according to an embodiment facilitates control of the etching rate for various metal-containing layers, for example, a metal-containing layer including molybdenum, and thus can be effectively used in various treatment processes for the metal-containing layer, for example, etching, cleaning, and polishing processes. Accordingly, by processing a metal-containing layer using the composition, a higher-quality semiconductor device can be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A composition comprising:
an oxidizing agent;
an acid; and
an etching controller, wherein
the etching controller comprises at least one compound represented by Formula 1, 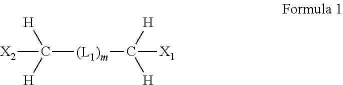
wherein in Formula 1,
X₁ is *—OH or *—SH,
X₂ is hydrogen, *—OH, or *—SH,
each L₁ is independently *—C(R₁)(R₂)—**, *—O—*′ or *—S—*′, provided that a number of *—O—*′ or *—S—*′ in (L₁)ₘ is 0 or 1,
m is an integer from 1 to 30,
when m is an integer from 2 to 30, each L₁ in (L₁)ₘ is identical to or different from another L₁ in (L₁)ₘ,
R₁ and R₂ are each independently hydrogen or a C₁-C₁₀ alkyl group, and
* and *′ each indicate a bonding site to a neighboring atom.

2. The composition of claim 1, wherein
the oxidizing agent comprises at least one of hydrogen peroxide, nitric acid, and ammonium sulfate.

3. The composition of claim 1, wherein
an amount of the oxidizing agent is 0.001 wt % to 50 wt %, based on 100 wt % of the composition.

4. The composition of claim 1, wherein
the acid is an inorganic acid.

5. The composition of claim 1, wherein
the acid comprises at least one of phosphoric acid, sulfuric acid, and hydrofluoric acid.

6. The composition of claim 1, wherein
an amount of the acid is 0.01 wt % to 90 wt %, based on 100 wt % of the composition.

7. The composition of claim 1, wherein
X₁ is *—OH,
X₂ is hydrogen or *—OH, and
each L₁ in (L₁)ₘ is independently *—C(R₁)(R₂)—*′ or *—O—*′.

8. The composition of claim 1, wherein
m is an integer from 1 to 6.

9. The composition of claim 1, wherein
the etching controller comprises at least one of a compound represented by Formula 1(1), a compound represented by Formula 1(2), or any combination thereof: 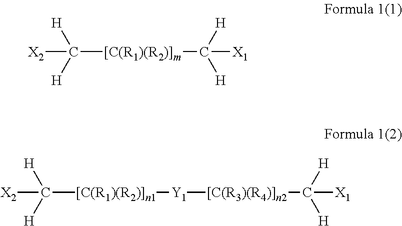
wherein, in Formulae 1 (1) and 1 (2),
X₁ is *—OH or *—SH,
X₂ is hydrogen, *—OH, or *—SH,
Y₁ is O or S,
m is an integer from 1 to 30,
n1 and n2 are each independently an integer from 0 to 29,
a sum of n1 and n2 is an integer from 0 to 29,
R₁ to R₄ are each independently hydrogen or a C₁-C₁₀ alkyl group, and
* is a bonding site with a neighboring atom.

10. The composition of claim 1, wherein
the etching controller comprises at least one of compounds represented by Formulae 2(1) to 2(8) and Formulae 3(1) to 3(13): 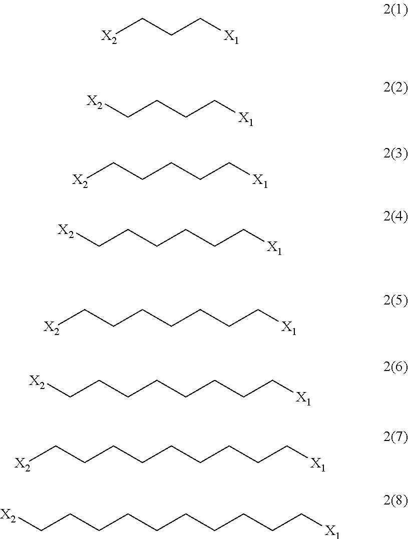 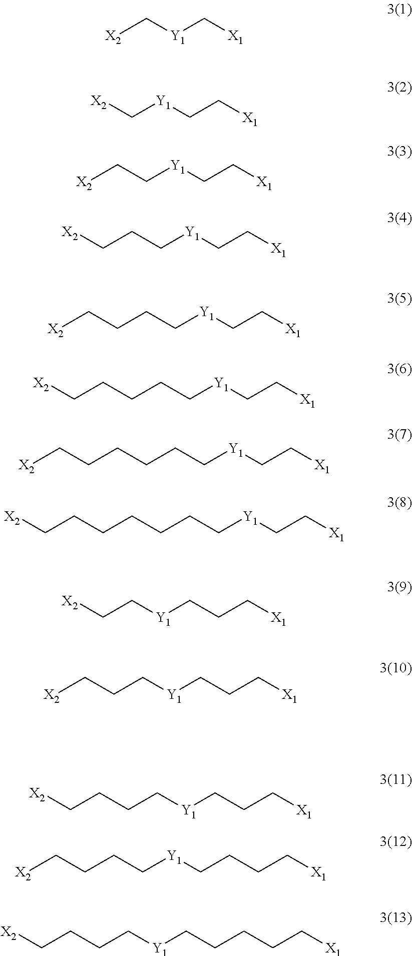
wherein, in Formulae 2(1) to 2(8) and 3(1) to 3(13),
X₁ is *—OH or *—SH,
X₂ is hydrogen, *—OH, or *—SH, and
Y₁ is O or S.

11. The composition of claim 1, wherein
the etching controller comprises at least one of Compounds E1 to E11:

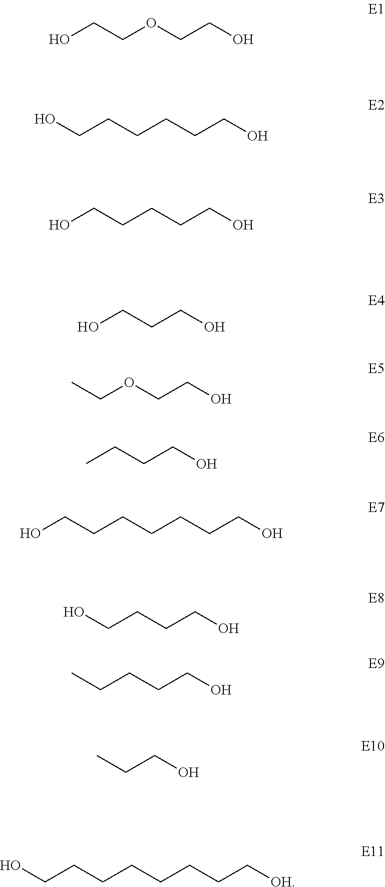

12. The composition of claim 1, wherein
an amount of the etching controller is 0.01 wt % to 20 wt %, based on 100 wt % of the composition.

13. The composition of claim 1, wherein
an amount of the oxidizing agent is 0.1 wt % to 5 wt %, based on 100 wt % of the composition,
an amount of the acid is 20 wt % to 60 wt %, based on 100 wt % of the composition, and
an amount of the etching controller is 1 wt % to 10 wt %, based on 100 wt % of the composition.

14. A method of treating a metal-containing layer, comprising:
preparing a substrate including a metal-containing layer thereon; and
contacting the metal-containing layer with the composition according to claim 1.

15. The method of claim 14, wherein
a metal in the metal-containing layer comprises titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), or any combination thereof.

16 The method of claim 14, wherein
the metal-containing layer comprises a metal, a metal nitride, a metal oxide, a metal oxynitride, or any combination thereof.

17. The method of claim 14, wherein
at least a portion of the metal-containing layer is etched, cleaned, or polished due to the contacting of the metal-containing layer with the composition.

18. The method of claim 14, wherein
the metal-containing layer comprises molybdenum (Mo).

19. The method of claim 14, wherein
the metal-containing layer further comprises titanium nitride, or
the metal-containing layer further comprises titanium nitride further comprising indium, aluminum, lanthanum, scandium, gallium, hafnium, zinc, tungsten, silicon, or any combination thereof.

20. A method of manufacturing a semiconductor device, comprising:
preparing a substrate including a metal-containing layer thereon;
contacting the metal-containing layer with the composition of claim 1; and
performing one or more subsequent manufacturing processes.
